(19) United States
(12) Patent Application Publication
(10) Pub. No.: US 2025/0321876 A1
(43) Pub. Date: Oct. 16, 2025

(54) MEMORY CONTROLLER AND OPERATION METHOD THEREOF

(71) Applicant: SAMSUNG ELECTRONICS CO., LTD., Suwon-si (KR)

(72) Inventors: Byeongho KIM, Suwon-si (KR); Suk Han Lee, Suwon-si (KR); Jung Ho Ahn, Seoul (KR); Hwayong Nam, Seoul (KR); Jaehyun Park, Seoul (KR); Sungmin Yun, Seoul (KR)

(73) Assignees: SAMSUNG ELECTRONICS CO., LTD., Suwon-si (KR); SEOUL NATIONAL UNIVERSITY R&DB FOUNDATION, Seoul (KR)

(21) Appl. No.: 19/002,383

(22) Filed: Dec. 26, 2024

(30) Foreign Application Priority Data
Apr. 16, 2024 (KR) 10-2024-0050775

(51) Int. Cl. G06F 12/02

(52) U.S. Cl. CPC G06F 12/0207; G06F 2212/305

(57) ABSTRACT

A memory controller includes a plurality of computing units and a controller. The plurality of computing units perform calculations related to a matrix multiplication. The controller identify first information indicating a plurality of vectors required for the calculations with respect to a plurality of rows of a matrix, identify second information indicating at least one row to which each of the plurality of vectors corresponds among the plurality of rows, and control the plurality of computing units to perform the calculations with respect to the plurality of rows by sequentially inputting the plurality of vectors into the plurality of computing units based on the first information and the second information.

### CROSS-REFERENCE TO RELATED APPLICATION(S)

This application claims the benefit of Korean Patent Application No. 10-2024-0050775, filed on Apr. 16, 2024, in the Korean Intellectual Property Office, the disclosure of which is incorporated herein by reference.

### BACKGROUND

### Technical Field

Example embodiments relate to a memory controller, and an operation method of the same.

### Description of the Related Art

Memory such as dynamic random access memory (DRAM) can store data for calculations. As calculations using high-capacity data are required, the time required for the operation of memory controller reading data stored in memory and the operation of processing calculations using the read data may be long. Accordingly, required is development of a method for operating a memory controller to improve the calculation performance of the memory controller when the memory controller performs calculations using data stored in the memory.

### SUMMARY

An aspect provides a memory controller with improved calculation performance by minimizing the number of accesses to the memory controller, and an operation method for the same.

he technical problems to be solved by the present disclosure are not limited to the technical problems described above, and other technical problems may be inferred from the following example embodiments.

Provided herein is a memory controller including: a plurality of computing units, wherein the plurality of computing units is configured to perform calculations related to a matrix multiplication; and a controller configured to: identify first information indicating a plurality of vectors required for the calculations with respect to a plurality of rows of a matrix, identify second information indicating at least one row to which each of the plurality of vectors corresponds among the plurality of rows, and control the plurality of computing units to perform the calculations with respect to the plurality of rows by sequentially inputting the plurality of vectors into the plurality of computing units based on the first information and the second information.

Also provided herein is an operation method of a memory controller including a plurality of computing units configured to perform calculations related to a matrix multiplication and a controller, the operation method including: identifying first information indicating a plurality of vectors required for the calculations with respect to a plurality of rows of a matrix, identifying second information indicating at least one row to which each of the plurality of vectors corresponds among the plurality of rows, and controlling the plurality of computing units to perform the calculations with respect to the plurality of rows by sequentially inputting the plurality of vectors into the plurality of computing units based on the first information and the second information.

Also provided herein is a non-transitory computer-readable recording medium having a program for executing the operation method on a computer.

Also provided herein is a memory system including: a host system including a memory device controller; and a plurality of memory controllers that operate according to commands received from the memory device controller, wherein the plurality of memory controllers includes a first memory controller, wherein the first memory controller includes: a plurality of computing units configured to perform calculations related to a matrix multiplication; and a controller configured to: identify first information indicating a plurality of vectors required for the calculations with respect to a plurality of rows of a matrix, identify second information indicating at least one row to which each of the plurality of vectors corresponds among the plurality of rows, and control the plurality of computing units to perform the calculations with respect to the plurality of rows by sequentially inputting the plurality of vectors into the plurality of computing units based on the first information and the second information.

Additional aspects of example embodiments will be set forth in part in the description which follows and, in part, will be apparent from the description, or may be learned by practice of the disclosure.

According to example embodiments, it is possible to minimize the number of operations to read information about a plurality of vectors by a memory controller sequentially inputting the plurality of vectors into a plurality of computing units based on first information and second information, and by the memory controller controlling the plurality of computing units to perform calculations on a plurality of rows. Accordingly, the time taken for the memory controller to perform the calculations may be reduced, and the amount of power consumed by the memory controller for the calculations with respect to the plurality of rows of the matrix may also be reduced.

Effects of the present disclosure are not limited to those described above, and other effects may be made apparent to those skilled in the art from the following description.

None of the description in this application should be read as implying that any particular element, step, or function is an essential element that must be included in the claim scope. The scope of patented subject matter is defined only by the claims. Moreover, none of the claims is intended to invoke 35 U.S.C. § 112(f) unless the exact words “means for” are followed by a participle. Use of any other term, including without limitation “mechanism,” “module,” “device,” “unit,” “component,” “element,” “member,” “apparatus,” “machine,” “system,” “processor,” or “controller,” within a claim is understood by the Applicant to refer to structures known to those skilled in the relevant art and is not intended to invoke 35 U.S.C. § 112(f).

### BRIEF DESCRIPTION OF THE DRAWINGS

These and/or other aspects, features, and advantages will become apparent and more readily appreciated from the following description of example embodiments, taken in conjunction with the accompanying drawings of which:

FIG. 1 is a diagram illustrating a memory controller according to an example embodiment;

FIG. 2 is a diagram illustrating a memory controller in more detail according to an example embodiment;

FIG. 3A is a diagram illustrating a memory system including a memory device and a host system according to an example embodiment;

FIG. 3B is a diagram illustrating a memory device according to an example embodiment;

FIG. 4 is a flowchart for explaining an operation method of a first controller according to an example embodiment;

FIG. 5 is a diagram illustrating a method of performing calculation related to matrix multiplication based on a plurality of rows of a sparse matrix and a target matrix according to an example embodiment;

FIG. 6 is a diagram for explaining the number of times a second controller transmits a command including address information to memory when calculation related to matrix multiplication is performed according to an example embodiment;

FIG. 7 is a diagram illustrating a method of selecting a preset number of plurality of rows among rows of a sparse matrix; and

FIG. 8 is a flowchart illustrating an operation method of a memory controller according to an example embodiment.

### DETAILED DESCRIPTION

Terms used in the example embodiments are selected from currently widely used general terms when possible while considering the functions in the present disclosure. However, the terms may vary depending on the intention or precedent of a person skilled in the art, the emergence of new technology, and the like. Further, in certain cases, there are also terms arbitrarily selected by the applicant, and in the cases, the meaning will be described in detail in the corresponding descriptions. Therefore, the terms used in the present disclosure should be defined based on the meaning of the terms and the contents of the present disclosure, rather than the simple names of the terms.

Throughout the specification, when a part is described as “comprising or including” a component, it does not exclude another component but may further include another component unless otherwise stated. Furthermore, terms such as “ . . . unit,” “ . . . group,” and “ . . . module” described in the specification mean a unit that processes at least one function or operation, which may be implemented as hardware, software, or a combination thereof.

Hereinafter, example embodiments of the present disclosure will be described in detail with reference to the accompanying drawings so that those of ordinary skill in the art to which the present disclosure pertains may easily implement them. However, the present disclosure may be implemented in multiple different forms and is not limited to the example embodiments described herein.

Hereinafter, example embodiments will be described in detail with reference to the drawings.

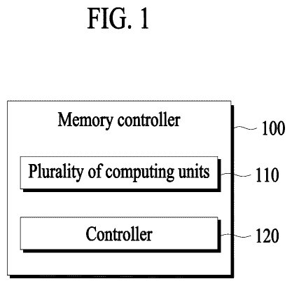

FIG. 1 is a diagram illustrating a memory controller according to an example embodiment.

Referring to FIG. 1, a memory controller 100 according to the example embodiment may include a plurality of computing units 110 and a controller 120. Here, the memory controller 100 may be a device for controlling the performance of various calculation using information read from memory. The memory controller 100 may be located close to the memory, and may be a device for controlling the performance of calculations using information read from memory. With regard thereto, the memory controller 100 may be called a near data processing (NDP) module or a near memory processing (NMP) module. Here, the memory may include the DRAM, but is not limited thereto. More specifically, the memory controller 100 may be a device for controlling various operations related to matrix multiplication including an operation of reading information on a vector from memory and an operation performing calculation related to matrix multiplication using the read information on the vector.

According to an example embodiment, calculation related to matrix multiplication performed in the memory controller 100 may be calculation related to sparse matrix multiplication. Here, a sparse matrix may represent a matrix in which most of the values of the elements of the matrix are zero. For example, only 10% or less of the elements may be non-zero. With regard thereto, among the elements of the sparse matrix, the elements whose value is 0 may be referred to as zero elements. Conversely, among the elements of the sparse matrix, elements of which values are not 0 may be referred to as non-zero elements. The target matrix that is the target of matrix multiplication with the sparse matrix may be a dense matrix. Here, the dense matrix may represent a matrix where most of the values of the elements of the matrix are non-zero. In other words, the target matrix may have a much larger capacity compared to the sparse matrix, and thus the target matrix being stored in memory rather being stored in a buffer (not illustrated) in the memory controller 100 is efficient in terms of storage space management efficiency. With regard thereto, at least some of the rows of the target matrix may be identified as a plurality of vectors required for calculation related to matrix multiplication, and the memory controller 100 may sequentially perform operations to read the plurality of vectors identified as vectors required for calculation related to matrix multiplication.

The plurality of computing units 110 may be computing units for performing calculation based on various information including information read from the memory. More specifically, each of the plurality of computing units 110 may be a computing unit to perform calculation related to matrix multiplication based on information on any one vector read from the memory among the plurality of vectors. In an example embodiment, each of the plurality of computing units 110 may be a multiply and accumulation (MAC) unit, but is not limited thereto. In another example embodiment, each of the plurality of computing units 110 may include an arithmetic and logical unit (ALU) and a computing unit for fused multiply-add (FMA).

According to an example embodiment, the controller 120 may control the overall operation of the memory controller 100. More specifically, the controller 120 may control the overall operation for calculations related to matrix multiplication of the memory controller 100.

According to an example embodiment, the controller 120 may identify information required for calculations related to matrix multiplication. More specifically, the controller 120 may identify first information about a plurality of vectors required for calculations with respect to the plurality of rows of the matrix and the second information about at least one row that each of the plurality of vectors corresponds. In an example embodiment, the plurality of vectors may be identified based on the columns of non-zero elements included in the plurality of rows. More specifically, among the rows of the target matrix, a row that multiplication is performed with non-zero elements included in the plurality of rows of the sparse matrix may be identified as a vector that is required for calculation related to the matrix multiplication. In another example embodiment, among a plurality of vectors, at least one row corresponding to a first vector may be identified based on the rows of non-zero elements included in the first column corresponding to the first vector.

According to an example embodiment, by inputting information related to calculation into the plurality of computing units 110, the controller 120 may control the plurality of computing units 110 to perform calculations on the plurality of rows. For example, by sequentially inputting the plurality of vectors into the plurality of computing units 110 based on the first information and the second information, the controller 120 may control the plurality of computing units 110 to perform calculations on the plurality of rows. The plurality of computing units 110 may perform calculation on the plurality of rows based on the input information including the information on the plurality of vectors.

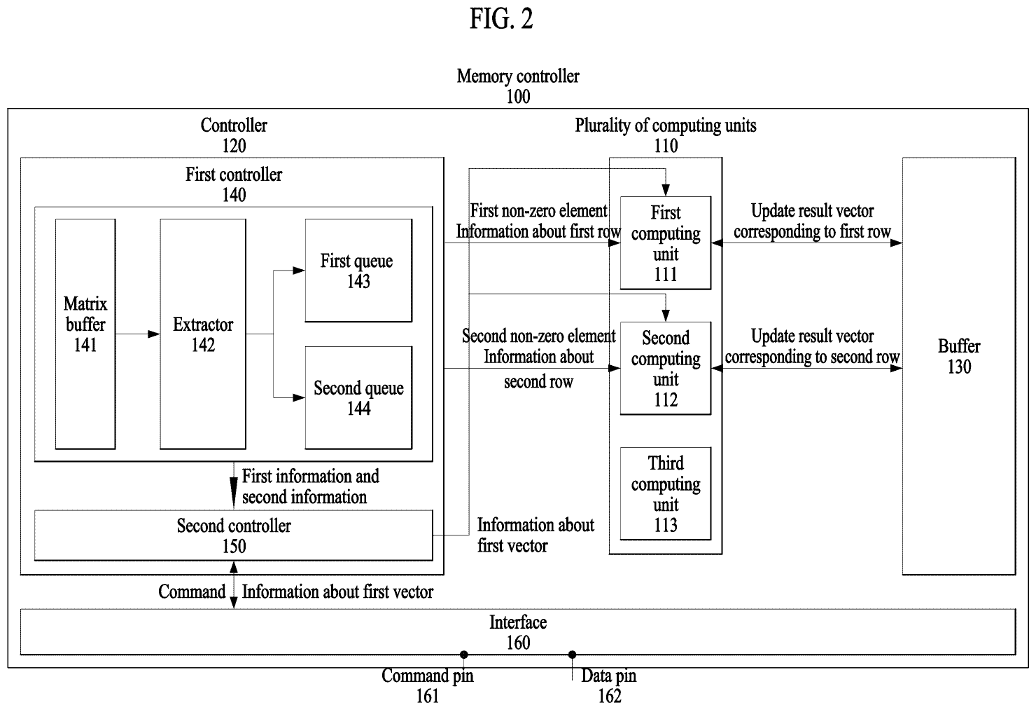

FIG. 2 is a diagram illustrating a memory controller in more detail according to an example embodiment.

More specifically, FIG. 2 is a diagram illustrating entire process of calculation related to matrix multiplication including operations in which the controller 120 including a first controller 140 and a second controller 150 controls the plurality of computing units 110 to perform calculations.

Referring to FIG. 2, the memory controller 100 may include the plurality of computing units 110, the controller 120, a buffer 130 and an interface 160. The controller 120 may include the first controller 140 and the second controller 150, and the first controller 140 may include a matrix buffer 141, an extractor 142, a first queue 143 and a second queue 144. Here, the first controller 140 may be located close to the memory and may perform operations to control the plurality of computing units 110 to perform calculations. With regard thereto, the first controller 140 may be called an NDP controller. When memory is a DRAM in an example embodiment, the second controller 150 may perform operations to control the DRAM. Here, the second controller 150 may be referred to as a DRAM controller. The extractor may be implemented by a CPU, processor executing instructions from memory, by custom hardware, or by a combination.

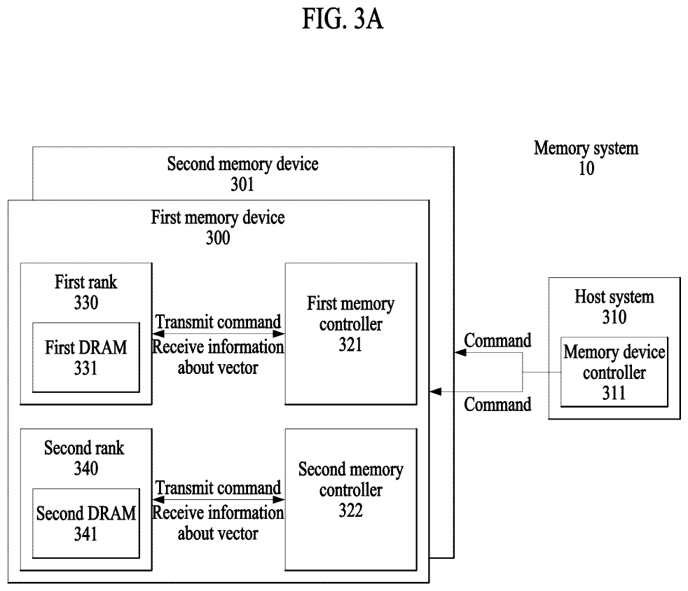

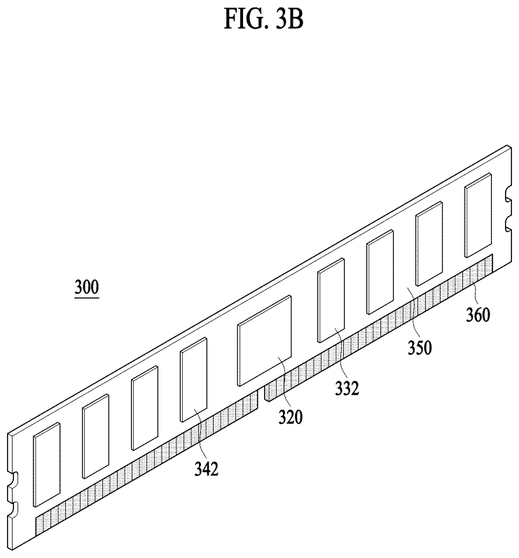

A sparse matrix may be stored in the matrix buffer 141. More specifically, most elements of the sparse matrix have zero values, and thus a compressed sparse matrix may be stored in the matrix buffer 141. For example, the compressed sparse matrix may be a sparse matrix compressed in either a compressed sparse row (CSR) format that compresses on a row basis or a compressed sparse column (CSC) format that compresses based on a column basis, but the compressed sparse matrix is not limited thereto. In the following, for convenience of explanation, the descriptions will be based on an uncompressed sparse matrix. Further, only a plurality of rows of a sparse matrix may be stored in the matrix buffer 141. The plurality of rows stored in the matrix buffer 141 may be determined by the host system's micro controller (not illustrated), and this will be specifically described with reference to FIG. 3.

According to an example embodiment, based on the sparse matrix stored in the matrix buffer 141, the extractor 142 may identify first information about a plurality of vectors required for calculation with respect to a plurality of rows and second information about at least one row that each of the plurality of vectors corresponds among the plurality of rows. More specifically, by sequentially searching for non-zero elements included in the plurality of rows for each column according to a preset first order, the extractor 142 may perform an operation to identify the plurality of vectors and at least one row to which each of the plurality of vectors corresponds. Here, sequentially searching each column according to the preset first order may be sequentially searching from a first column to the last column, but the sequentially searching is not limited thereto.

Information identified by the extractor 142 may be divided, and separately stored into the first queue 143 and the second queue 144. According to an example embodiment, the first information may be stored in the first queue 143. The first information may include address information of a plurality of vectors stored in the memory. In other words, the first information may include memory address information for accessing each of the plurality of vectors. For example, the vectors of the target matrix stored in the memory may be distinguished only by information about the row of the target matrix to which each of the plurality of vectors corresponds, and thus the address information stored in the first queue 143 may be index information indicating the row of the target matrix corresponding to the vector. In an example embodiment, the index of the vector corresponding to the i-th row of the target matrix may be i−1, but is not limited thereto. According to another example embodiment, the second information may be stored in the second queue 144. The second information may include the index information of the row to which each of the plurality of vectors corresponds among the plurality of rows. Among the plurality of rows, when a first vector corresponds to a first row and a second row, the second information related to the first row may include first index information of the first row and second index information of the second row. The index representing the i-th row of the sparse matrix may be i−1, but is not limited thereto.

According to an example embodiment, the first queue 143 and the second queue 144 may have a first in first out (FIFO) data structure. With regard thereto, the first information about the vector identified first by the extractor 142 may be stored first in the first queue 143. In other words, the first information about the plurality of vectors may be stored in order in the first queue 143 according to a second order with respect to the plurality of vectors. Further, the second information about at least one row to which each of the plurality of vectors corresponds may be sequentially stored in the second queue 144 according to the second order with respect to the plurality of vectors. Here, the second order for the plurality of vectors may be the same as the order of an order in which the plurality of vectors are identified by the extractor 142, an order in which the plurality of vectors are stored in the first queue 143, an order in which the plurality of vectors are transmitted to the second controller 150 and an order in which the second controller 150 reads the plurality of vectors from the memory. For example, the second order with respect to the plurality of vectors may be an ascending order of the plurality of rows in the target matrix corresponding to the plurality of vectors, but the second order is not limited thereto. Further, the information stored in the first queue 143 and the second queue 144 may be deleted after calculation of the plurality of rows is complete.

According to an example embodiment, the first controller 140 may sequentially transmit the first information and the second information to the second controller 150.

More specifically, the first queue 143 and the second queue 144 have the FIFO data structure, and thus the first controller 140 may sequentially transmit the first information and the second information that are first stored in the first queue 143 and the second queue 144 to the second controller 150. In the second order with respect to the plurality of vectors, among the plurality of vectors, any one vector may be included only once without overlapping, and thus the number of times that the first information and the second information is transmitted to the second controller 150 may be equal to the number of the plurality of vectors. In other words, an operation in which the second controller 150 reads one vector among the plurality of vectors from the memory is performed only once, and thus each of the plurality of vectors may be called a unique vector.

According to an example embodiment, the second controller 150 may be a controller for controlling the memory. More specifically, the second controller 150 may be a controller for performing an operation to access data stored in the memory. With regard thereto, the second controller 150 may perform overall operations to control the memory, including reading data stored in the memory and writing data to the memory. For example, the second controller 150 may sequentially transmit commands including address information to the memory, and sequentially receive information about the plurality of vectors from the memory. More specifically, based on the second order for the plurality of vectors, in response to receiving the first information and the second information about any one vector among the plurality of vectors from the first controller 140, the second controller 150 may transmit a command including address information about the corresponding vector to the memory. Here, the command may include to read information about any one vector stored in the memory based on the address information and to return the information about the vector to the second controller 150. With regard thereto, the address information included in the command may include information about a location in the memory of a first element of the vector corresponding to the first information and information about the size of the vector. Accordingly, the second controller 150 may receive the information about the vector corresponding to the command.

According to an example embodiment, the second controller 150 may control the memory through the interface 160. Here, the interface 160 may be a device that allows interaction between the memory controller 100 and an external device. More specifically, the interface 160 may be an interface that allows interaction between the memory controller 100 and an external device such as memory or a memory device controller. For example, the interface 160 may be a double date rate (DDR) physical layer, but is not limited thereto. The interface 160 may be connected to a command pin 161 for transmitting and receiving commands to and from an external device and a data pin 162 for transmitting and receiving data to and from an external device. For example, the command pin 161 may correspond to DDR. command/address (C/A), and the data pin 162 may correspond to DDR. data queuing (DQ) which is a DDR data line, but the command pin 161 and the data pin 162 are not limited thereto. With regard thereto, the command transmitted from the second controller 150 may be transmitted to the memory through the command pin 161, and the information about the vector transmitted from the memory may be transmitted to the second controller 150 through the data pin 162. In the following, described are the process of performing calculation on the first vector read from memory among the plurality of vectors.

According to an example embodiment, the plurality of computing units 110 may include two or more computing units to perform calculations based on various information, including information read from the memory. With regard thereto, among the plurality of vectors, some vectors may correspond to two or more rows, and thus in order to process the calculations for the corresponding vectors in parallel, the plurality of computing units 110 may include two or more computing units. Referring to FIG. 2, the plurality of computing units 110 may include a first computing unit 111, a second computing unit 112 and a third computing unit 113, which are three computing units, but the present disclosure is not limited thereto.

According to an example embodiment, the second information may include information about a first row and a second row to which the first vector corresponds. The calculation for the first row and the calculation for the second row may be performed in parallel.

In the first computing unit 111, calculation for the first row may be performed. With regard thereto, the controller 120 may control the operation of inputting information about the first vector read by the second controller 150 into the first computing unit 111, and the operation of inputting information about a first non-zero element stored in the matrix buffer 141 and information about the first row stored in the second queue 144 into the first computing unit 111. More specifically, by simultaneously inputting the information about the first vector, the information about the first non-zero element and the information about the first row into the first computing unit 111, the controller 120 may control the first computing unit 111 to perform calculation for the first row. Here, the first non-zero element may be an element in a column corresponding to the first row and the first vector of the sparse matrix. The first computing unit 111 may perform scalar multiplication based on the first vector and the first non-zero element.

When calculation for the first row is performed in the first computing unit 111, calculation for the second row may be performed in parallel in the second computing unit 112. With regard thereto, the controller 120 may control the operation of inputting the information about the first vector read by the second controller 150 into the second computing unit 112, and the operation of inputting information about a second non-zero element stored in the matrix buffer 141 and information about the second row stored in the second queue 144 into the second computing unit 112. More specifically, by simultaneously inputting the information about the first vector, the information about the second non-zero element and the information about the second row into the second computing unit 112, the controller 120 may control the second computing unit 112 to perform calculation for the second row. Here, the second non-zero element may be an element in a column corresponding to the second row and the first vector of the sparse matrix. The second computing unit 112 may perform scalar multiplication based on the first vector and the second non-zero element.

Although not illustrated in FIG. 2, the number of rows corresponding to a specific vector may be greater than the number of plurality of computing units. For example, if the number of rows corresponding to a specific vector is 4, the calculation for three rows may be performed first in the first computing unit 111, the second computing unit 112 and the third computing unit 113. Afterwards, calculation for the remaining one row may be performed in any one of the first computing unit 111, the second computing unit 112 and the third computing unit 113.

Further, even though not illustrated in FIG. 2, according to an example embodiment, the controller 120 may control the operation of inputting information about the vector read by the second controller 150 into the plurality of computing units 110, and the operation of inputting information about rows stored in the second queue 144 into the plurality of computing units 110. With regard thereto, when the values of the non-zero elements of the sparse matrix are all 1, the result of performing scalar multiplication based on the vector and the non-zero element may be the same as the non-zero element, and thus in order to increase the efficiency of calculations related to the matrix multiplication, the controller 120 may not perform the operation of inputting any one non-zero element included in the sparse matrix.

According to an example embodiment, the buffer 130 may store a result vector corresponding to each row of the sparse matrix. With regard thereto, when calculation for a specific row is performed in any one computing unit among the plurality of computing units 110, the result vector corresponding to the specific row may be updated based on calculations in the computing unit corresponding to the specific row. For example, the result vector corresponding to the first row may be updated based on the scalar multiplication based on the first vector and the first non-zero element. More specifically, a vector according to a scalar multiplication based on the first vector and the first non-zero element and a vector according to a scalar addition between result vectors corresponding to the existing first row may be calculated as a result vector corresponding to the updated first row. Similarly, the result vector corresponding to the second row may be updated based on the scalar multiplication based on the first vector and the second non-zero element. More specifically, a vector according to a scalar multiplication based on the first vector and the second non-zero element and a vector according to a scalar addition between existing result vectors may be calculated as a result vector corresponding to the updated second row.

FIG. 2 illustrates that the controller 120 controls the plurality of computing units 110 to perform calculation for the first vector, but the present disclosure is not limited thereto. According to an example embodiment, the second order with respect to the plurality of vectors may include an order in which the first controller 140 transmits the first information about the first vector to the second controller 150 and then the first controller 140 transmits the first information about the second vector to the second controller 150. Accordingly, the controller 120 may control the plurality of computing units 110 to perform calculations based on the first vector and then perform calculations based on the second vector. Further, the second order with respect to the plurality of vectors may include that the first controller 140 finally transmits the first information about a third vector to the second controller 150. Here, when the plurality of computing units 110 perform calculation based on the third vector, the calculation for the plurality of rows may be terminated.

FIG. 2 merely illustrates that the first controller 140 transmits both the first information and the second information to the second controller 150, but the present disclosure is not limited thereto. For example, the first controller 140 may transmit only the first information about the first vector to the second controller 150. With regard thereto, since the second controller 150 does not receive the second information, the information about the first vector may be transmitted to all of the plurality of computing units 110. Accordingly, the first controller 140 may control the calculation to be performed only in a computing unit corresponding to the second information about the first vector among the plurality of computing units 110. With regard thereto, the first controller 140 may transmit the information about the first non-zero element and the first row to the first computing unit 111, transmit the information about the second non-zero element and the second row to the second computing unit 112, and transmit a zero element to the third computing unit 113. Calculations in the first computing unit 111 and the second computing unit 112 may be substantially the same as what is illustrated in FIG. 2. On the other hand, the third computing unit 113 may perform scalar multiplication based on the zero-element and the first vector, and as a result of the scalar multiplication, a vector with zero elements may be calculated. The calculation in the third computing unit 113 may not be reflected in the update of the result vector stored in the buffer 130.

FIG. 3A is a diagram illustrating a memory system including a memory device and a host system according to an example embodiment.

A memory system 10 may be a system for processing calculations related to matrix multiplication in parallel using a memory device equipped with a plurality of memories. The memory system 10 may include a plurality of memory devices and a host system 310 for controlling the plurality of memory devices. Here, the memory device may be a memory module composed of a plurality of memory controllers for performing various calculations using a plurality of memories and information read from the plurality of memories. According to an example embodiment, the memory devices may be dual in-line memory modules (DIMM). Referring to FIG. 3A, the plurality of memory devices may include a first memory device 300 and a second memory device 301. In an example embodiment, the memory may be a DRAM, but is not limited thereto. In another example embodiment, the memory may be volatile memory such as cache memory, registers and static random access memory (SRAM).

The host system 310 may be a system for controlling a memory device equipped with a plurality of memories to perform calculations in parallel. More specifically, the host system 310 may include a central processing unit (CPU), a controller or an application specific integrated circuit (ASIC). Further, for example, the host system 310 may include memory chips such as the DRAM, SRAM, phase-change RAM (PRAM), magneto resistive RAM (MRAM), ferroelectric RAM (FeRAM), and resistive RAM (RRAM).

Referring to FIG. 3A, the host system 310 may include a memory device controller 311. In order to minimize the time required to perform calculations related to matrix multiplication using high-capacity data stored in the DRAM, the memory device controller 311 may control calculations related to matrix multiplication to be performed separately in the plurality of memory controllers included in each of the plurality of memory devices. More specifically, the memory device controller 311 may control calculation to be performed, the calculation related to matrix multiplication between the plurality of rows corresponding to each of the plurality of memory controllers and the target matrix. Here, the plurality of rows may be a set number of rows among the rows of the sparse matrix. Here, the set number may be based on the size of the buffer 130 of the memory controller 100. With regard thereto, the larger the size of the buffer 130 of the memory controller 100, the more result vectors can be stored, and thus the set number may be set larger as the size of the buffer 130 of the memory controller 100 is larger.

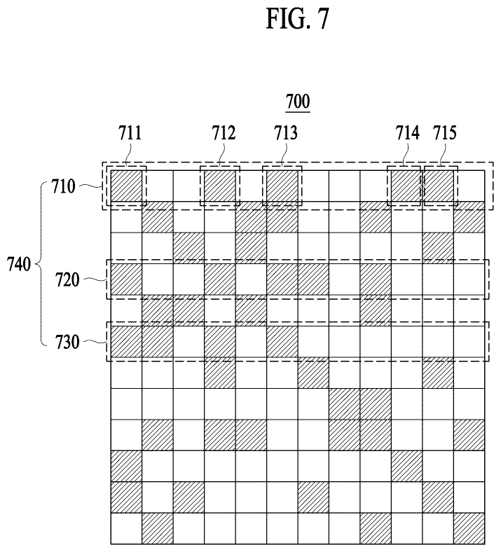

According to an example embodiment, the plurality of rows corresponding to each of the plurality of memory controllers may be determined in order for non-zero elements included in the plurality of rows to be placed in an identical column in a maximum number. The memory device controller 311 may transmit a command including information about the determined plurality of rows to a memory controller of each of the plurality of memory devices. The memory controller 100 may receive the command from the memory device controller 311 through the interface 160. FIG. 2 illustrates only one interface 160, but the present disclosure is not limited thereto. For example, the interface interacting with the memory device controller 311 and the interface interacting with the DRAM may be separately included in the memory controller 100. Specific methods of selecting a set number of plurality of rows among the rows of a sparse matrix will be described in detail with reference to FIG. 7.

The first memory device 300 may include a first memory controller 321, a second memory controller 322, a first rank 330 including a first DRAM 331 and a second rank 340 including a second DRAM 341. Here, each of the first memory controller 321 and the second memory controller 322 may correspond to the memory controller 100. With regard thereto, in the first memory controller 321, calculations with respect to the plurality of rows included in the command received from the memory device controller 311 may be performed. Further, the rank may be a block for distinguishing a plurality of DRAMs included in the memory device. With regard thereto, each of the plurality of memory controllers included in the memory device may read information about vectors from the DRAM included in the corresponding rank. For example, the first memory controller 321 may transmit a command to the first DRAM 331 included in the first rank 330, and receive information about a vector from the first DRAM 331. Similarly, the second memory controller 322 may transmit a command to the second DRAM 341 included in the second rank 340, and receive information about the vector from the second DRAM 341.

FIG. 3B is a diagram illustrating a memory device according to an example embodiment.

Referring to FIG. 3B, the first memory device 300 may include a plurality of memory chips mounted on a board 350. The first memory device 300 may further include a buffer chip 320 that provides commands and address information to the plurality of memory chips and input/output pads 360 provided at one end of the board 350. The input/output pads 360 may be connected to the data input/output paths of each of the plurality of memory chips. With regard thereto, the input/output pads 360 may correspond to the command pin 161 and the data pin 162.

Each of the plurality of memory chips including a memory chip 332 and a memory chip 342 may include the memory of the first memory device 300. For example, the plurality of memory chips including the memory chip 332 and the memory chip 342 may include the first DRAM 331 and the second DRAM 341. Further, the buffer chip 320 may provide commands and address information to the plurality of memory chips included in the first memory device 300. For example, the buffer chip 320 may include the first memory controller 321 that provides commands and address information to the first DRAM 331 and the second memory controller 322 that provides commands and address information to the second DRAM 341.

FIG. 3B illustrates that the first memory device 300 includes eight memory chips, but it is a mere example, and the present disclosure is not limited thereto. The number of memory chips may vary depending on the data storage capacity of the first memory device 300 or each of the memory chips. For example, the first memory device 300 may include 16 memory chips. When the memory device containing eight memory chips and the memory device containing 16 memory chips have the same data storage capacity, the data storage capacity of eight memory chips may be twice that of 16 memory chips. Further, the number of data input/output paths connected to each of the memory chips of the memory device containing eight memory chips may be twice the number of data input/output paths connected to each of the memory chips of the memory device containing 16 memory chips.

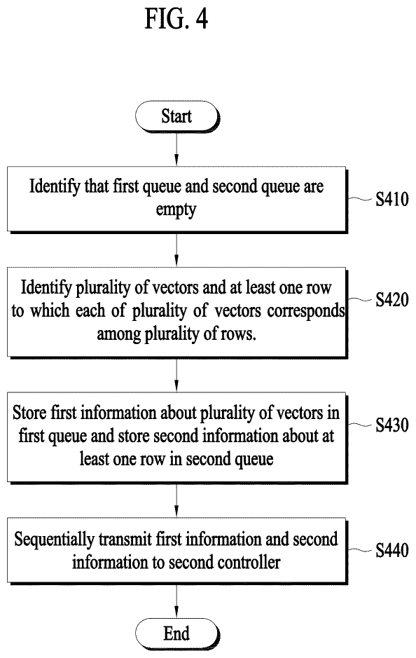

FIG. 4 is a flowchart for explaining an operation method of a first controller according to an example embodiment.

Each operation of the method for operating the first controller 140 of FIG. 4 may be performed by the first controller 140 described above, and thus descriptions that overlap the descriptions with reference to FIGS. 1 to 3 will be omitted. It is apparently understood that each operation of the method of operating the first controller 140 may be partially changed and/or replaced, or some of the sequences between operations may be changed within the scope of the present disclosure clearly understood by those skilled in the art to which the example embodiments of the present disclosure belong.

In operation S410, the first controller 140 may identify that the first queue 143 and the second queue 144 are empty.

According to an example embodiment, information stored in the first queue 143 and the second queue 144 may be deleted in response to completion of calculations related to matrix multiplication. In other words, the first queue 143 and the second queue 144 being empty may indicate that there is no calculation related to matrix multiplication currently being performed in the memory controller 100, and the calculation performed just before is already completed.

In operation S420, the first controller 140 may identify the plurality of vectors and at least one row to which each of the plurality of vectors corresponds among the plurality of rows.

According to an example embodiment, the first controller 140 may extract first information about the plurality of vectors required for calculation of the plurality of rows of the matrix and second information about at least one row to which each of the plurality of vectors corresponds among the plurality of rows. More specifically, by sequentially searching for non-zero elements included in the plurality of rows for each column according to a preset first order, the first controller 140 may extract the plurality of vectors and at least one row to which each of the plurality of vectors corresponds. Here, extracting the plurality of vectors and at least one row corresponding to each of the plurality of vectors may be sequentially extracting the plurality of vectors and at least one row corresponding to each of the plurality of vectors based on the second order for the plurality of vectors.

In operation S430, the first controller 140 may store the first information about the plurality of vectors in the first queue 143 and store the second information about at least one row in the second queue 144.

According to an example embodiment, when all first information about all vectors required for calculation of the plurality of rows of the matrix is extracted, the first controller 140 may store the first information about the plurality of vectors in the first queue 143 and store the second information about at least one row in the second queue 144. The first queue 143 and the second queue 144 may have the FIFO data structure, and thus the first information identified in operation S420 may be sequentially stored in the first queue 143 and the second information identified in operation S420 may be sequentially stored the second queue 144 based on the second order, which is the order in which the plurality of vectors are identified.

In operation S440, the first controller 140 may sequentially transmit the first information and the second information to the second controller 150.

According to an example embodiment, the first queue 143 and the second queue 144 have the FIFO data structure, and thus the first controller 140 may sequentially transmit the first information and the second information to the second controller 150 based on the second order, which is the order in which the first information and the second information are stored in the first queue 143 and the second queue 144. For example, the first controller 140 may transmit the first information about the first vector and the second information about at least one row corresponding to the first vector which are very first stored in the first queue 143 and the second queue 144, to the second controller 150. Afterwards, the first controller 140 may transmit the first information about the second vector which is identified after the first vector and the second information about at least one row corresponding to the second vector to the second controller 150. Until all first information about the plurality of vectors is transmitted to the second controller 150, the operation of transmitting first information and second information may be repeated by the first controller 140. With regard thereto, the total number of times that first information and second information are transmitted to the second controller 150 may be equal to the number of plurality of vectors. When all first information about plurality of vectors is transmitted to the second controller 150, calculation with respect to the plurality of rows of the sparse matrix is complete, and thus all information stored in the first queue 143 and the second queue 144 may be deleted.

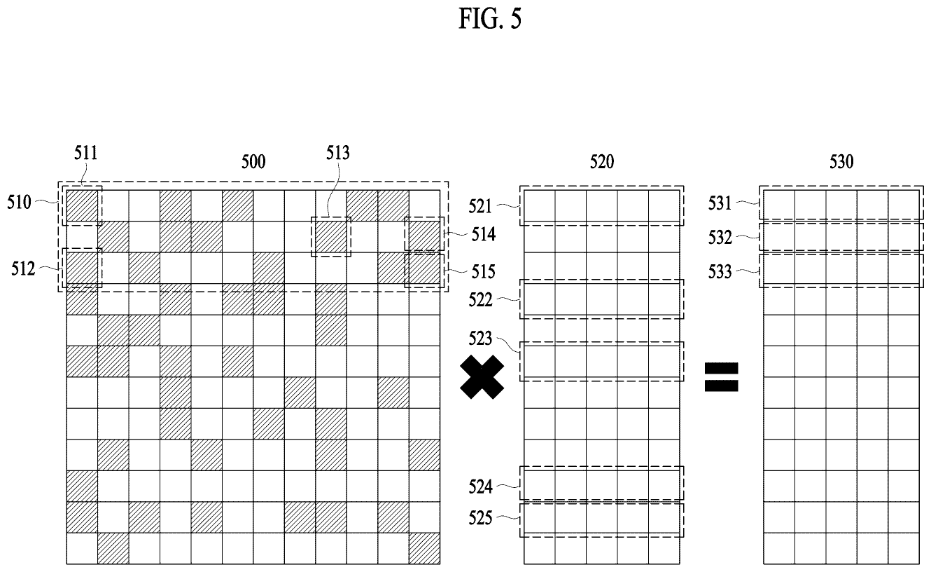

FIG. 5 is a diagram illustrating a method of performing calculation related to matrix multiplication based on a plurality of rows of a sparse matrix and a target matrix according to an example embodiment.

According to an example embodiment, a sparse matrix 500 may be a matrix in which most of the values of the elements of the matrix are zero. According to an example embodiment, the sparse matrix 500 may be a sparse matrix used in calculations related to graph neural networks (GNN). Here, the GNN may be an artificial neural network for analyzing and modeling graph structures. The graph may be a data structure made up of nodes and edges that represent relationships between two nodes. With regard thereto, an i-th row and an i-th column of the sparse matrix corresponding to the graph may correspond to an i-th node, and an element corresponding to (i, j) and (j, i) of the sparse matrix corresponding to the graph may correspond to an edge between an i-th node and a j-th node. For example, when a first node and a second node are connected, an element of the sparse matrix corresponding to the first node and the second node may be a non-zero element, and when the first node and the second node are not connected, the element of the sparse matrix corresponding to the first node and the second node may be a zero element. Due to the nature of the graph, the sparse matrix used in GNN-related calculations may be a symmetric matrix, and the non-zero element included in the sparse matrix used in GNN-related calculations may be 1. The sparse matrix 500 may be a sparse matrix used in GNN-related calculations or may be a sparse matrix used in calculations related to a deep learning recommendation model (DLRM), but the sparse matrix 500 is not limited thereto.

According to an example embodiment, each row of the sparse matrix 500 may include non-zero elements. More specifically, each row of the sparse matrix 500 may include the same number of five non-zero elements, but is not limited thereto. Referring to FIG. 5, a first element, a fourth element, a sixth element, a 10th element and 11th element of the first row of the sparse matrix 500 may be non-zero elements, and the other elements in the first row may be zero elements.

According to an example embodiment, a target matrix 520 may be a matrix composed of vectors that are the subject of matrix multiplication with the sparse matrix 500. As described above, rows of the sparse matrix 500 may correspond to at least some vectors of the target matrix 520. More specifically, vectors of the target matrix 520 corresponding to rows of the sparse matrix 500 may be identified based on columns corresponding to non-zero elements included in the rows of the sparse matrix 500. Referring to FIG. 5, vectors corresponding to the first row of the sparse matrix 500 may include a vector 521, a vector 522, a vector 523, a vector 524 and a vector 525 of the target matrix 520. The vector 521 of the target matrix 520 may correspond to a non-zero element 511, which is the first element of the first row of the sparse matrix 500, the vector 522 of the target matrix 520 may correspond to the fourth element of the first row of the sparse matrix 500, the vector 523 of the target matrix 520 may correspond to the sixth element of the first row of the sparse matrix 500, the vector 524 of the target matrix 520 may correspond to the 10th element of the first row of the sparse matrix 500, and the vector 525 of the target matrix 520 may correspond to the 11th element of the first row of the sparse matrix 500.

According to an example embodiment, a result matrix 530 may be a matrix that is the result of calculation related to matrix multiplication based on the sparse matrix 500 and the target matrix 520. More specifically, the result vector corresponding to the i-th row of the result matrix 530 may be calculated based on the non-zero elements included in the i-th row of the sparse matrix 500 and the vector of the target matrix 520 corresponding to the i-th row. For example, a result vector 531 corresponding to the first row of the result matrix 530 may be calculated based on the non-zero elements included in the first row of the sparse matrix 500 and the vector of the target matrix 520 corresponding to the first row of the sparse matrix 500, and a result vector 532 corresponding to a second row of the result matrix 530 may be calculated based on non-zero elements included in the second row of the sparse matrix 500 and a vector of the target matrix 520 corresponding to the second row of the sparse matrix 500, and a result vector 533 corresponding to a third row of the result matrix 530 may be calculated based on non-zero elements included in the third row of the sparse matrix 500 and a vector of the target matrix 520 corresponding to the third row of the sparse matrix 500.

According to an example embodiment, the memory device controller 311 may control that calculations related to multiplication of the sparse matrix 500 are performed separately in the first memory device 300 and the second memory device 301. More specifically, the memory device controller 311 may control the first memory device 300 to perform calculation of the first row to the sixth row of the sparse matrix 500, and the memory device controller 311 may control the second memory device 301 to perform calculation of the seventh row to the 12th row of the sparse matrix 500. Calculations for the first row to the third row may be performed in the first memory controller 321 of the first memory device 300, and calculations for the fourth row to the sixth row may be performed in the second memory controller 322 of the first memory device 300. In other words, calculations related to the multiplication of the sparse matrix 500 may be performed separately in a plurality of memory controllers included in each of the plurality of memory devices. Hereinafter, described are specific example embodiments for identifying a plurality of vectors and at least one row to which each of the plurality of vectors corresponds that are required for calculations of the first row to the third row of the sparse matrix 500. With regard thereto, a plurality of rows 510 in the sparse matrix 500 may include the first row to the third row of the sparse matrix 500.

According to an example embodiment, by sequentially searching for non-zero elements included in the plurality of rows for each column according to a preset first order, the extractor 142 may identify a plurality of vectors and at least one row to which each of the plurality of vectors corresponds. More specifically, the extractor 142 sequentially searches for non-zero elements included in the plurality of rows from the first row to the last row, and when a column contains a non-zero element, sequentially performed are the operation of identifying first information about the vector corresponding to the column of the non-zero element and second information about the row of the non-zero element, the operation of determining whether the next column contains a non-zero element, and when a non-zero element is not contained in the column, the operation of determining whether the next column contains a non-zero element is performed.

For example, the extractor 142 may identify that the first column of the plurality of rows 510 includes two non-zero elements which are the non-zero element 511 and a non-zero element 512. With regard thereto, a vector corresponding to the first column may be identified as a vector required for calculation for the plurality of rows, and the first row corresponding to the non-zero element 511 and the third row corresponding to the non-zero element 512 may be identified as rows that correspond to the vector corresponding to the first column. The extractor 142 that completed the identification may perform the operation of determining whether the next column, which is the second column, contains a non-zero element. As similar operations are performed repeatedly, the extractor 142 may identify that the eighth column of the sparse matrix 500 does not contain a non-zero element. In other words, the vector corresponding to the eighth column may be identified as an unnecessary vector for calculation for the plurality of rows. Subsequently, the extractor 142 may identify that the next column, which is the ninth column, contains a non-zero element 513. With regard thereto, the vector corresponding to the ninth column may be identified as a vector required for calculation of the plurality of rows, and the second row corresponding to the non-zero element 513 may be identified as the row corresponding to the vector corresponding to the ninth column. Finally, the extractor 142 may identify that the 12th column includes two non-zero elements, a non-zero element 514 and a non-zero element 515. With regard thereto, the vector corresponding to the 12th column may be identified as a vector required for calculation of the plurality of rows, and the second row corresponding to the non-zero element 514 and the third row corresponding to the non-zero element 515 may be identified as the rows corresponding to the vector corresponding to the 12th column. As such, a plurality of vectors may be identified without overlapping based on the second order for the plurality of vectors.

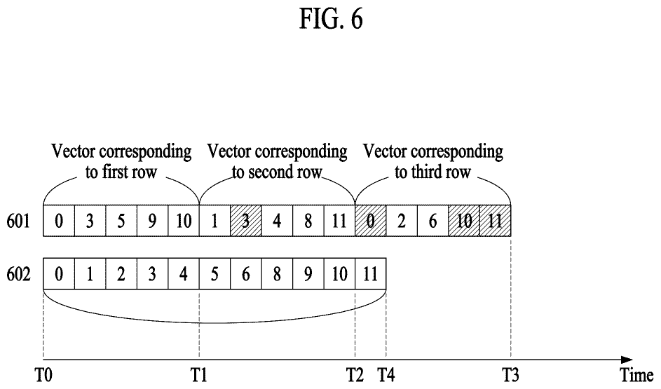

FIG. 6 is a diagram for explaining the number of times a second controller transmits a command including address information to memory when calculation related to matrix multiplication is performed according to an example embodiment.

An order 602 may represent an order in which the second controller 150 transmits a command including address information to memory when a calculation related to matrix multiplication is performed for the plurality of rows 510 according to the example embodiment of FIG. 5. As described above, indexes included in the order 601 and the order 602 may correspond to each row of the target matrix 520. For example, the i-th row of the target matrix 520 may correspond to index i−1.

With regard to the order 602, according to an example embodiment, the first controller 140 may perform an operation to identify a plurality of vectors required for calculation of the plurality of rows 510 without overlapping according to the second order for the plurality of vectors. Accordingly, information about the plurality of vectors may be stored in the first queue 143 in order according to the second order. Further, the first controller 140 may sequentially transmit the first information about the vectors stored in the first queue 143 to the second controller 150, and the second controller 150 may sequentially transmit commands including the first information to memory. Referring to FIG. 6, the second controller 150 may sequentially transmit the commands including address information regarding the plurality of vectors corresponding to the plurality of rows 510 from T0 to T4 to the memory. In other words, the number of times the commands are sequentially transmitted to the memory based on the order 602 may be 11, which is the number of columns corresponding to the non-zero elements included in the plurality of rows 510. Further, it may take as much time as T4 for the commands to be sequentially transmitted to the memory based on the order 602.

On the other hand, when calculations related to matrix multiplication are performed based on each of the plurality of rows 510 and the target matrix 520, the number of times a command is transmitted to the memory may be 15 times. More specifically, a command including address information about five plurality of vectors corresponding to the first row of the sparse matrix 500 from T0 to T1 may be transmitted to the memory, a command including address information about five plurality of vectors corresponding to the second row of the sparse matrix 500 from T1 to T2 may be transmitted to the memory, and a command including address information about five plurality of vectors corresponding to the third row from T2 to T3 may be transmitted to the memory. In other words, the number of times a command is sequentially transmitted to the memory based on the order 602 may be less than 15, which is the number of times that a command is transmitted to the memory based on the order 601.

In other words, when calculations related to the matrix multiplication are performed for the plurality of rows 510 according to the example embodiment of FIG. 5, the command including address information for each vector is transmitted to the memory only once, and thus the number of accesses to the memory may be reduced. Specifically, even though FIG. 5 illustrates the size of the sparse matrix 500 as 12×12 and the size of the target matrix 520 as 12×5, the size of the vector included in the target matrix 520 may be very large. For example, the size of the vector included in the target matrix 520 may be very large, exceeding 1K. As such, when calculations related to matrix multiplication using high-capacity vectors are performed, the time required to read a specific vector may be significantly longer. With regard thereto, as the number of accesses to the memory decreases, the time required to read a specific vector may be greatly reduced.

FIG. 7 is a diagram illustrating a method of selecting a preset number of plurality of rows among rows of a sparse matrix.

According to an example embodiment, a difference, which is the difference between the number of times a command including address information is transmitted to the memory when calculations related to matrix multiplication are sequentially performed based on each row and the target matrix and the number of times a command including address information is transmitted to the memory when calculations related to matrix multiplication according to the example embodiment of FIG. 6 are performed, may be based on the number of times non-zero elements included in the plurality of rows overlap in the same row. More specifically, the more non-zero elements included in the plurality of rows overlap in the same row, the greater the difference in counts may be calculated. Referring to FIG. 6, a difference, which is the difference between the number of times a command is sequentially transmitted to the memory based on the order 601 and the number of times a command is sequentially transmitted to the memory based on the order 602, may be 4 that is the number of times a non-zero element included in the plurality of rows 510 overlaps in the same row.

In other words, when a plurality of rows are configured in order for non-zero elements among the rows of a sparse matrix to be placed in an identical column in a maximum number, the number of operations in which the second controller 150 reads information about a vector from the memory may be minimized. With regard thereto, a command transmitted by the memory device controller 311 to a plurality of memory devices may include information about a plurality of rows corresponding to each of the plurality of memory controllers. Here, the plurality of rows may be determined by the memory device controller 311 in order for non-zero elements included in the set number of rows of the matrix to be placed in an identical column in a maximum number. However, it may also take time to determine the plurality of rows corresponding to each of the plurality of memory controllers. In other words, determining the plurality of rows corresponding to each of the plurality of memory controllers within a short time while ensuring that many non-zero elements included in the plurality of rows are placed in the same column may be efficient in terms of reducing the total time required for calculations related to matrix multiplication.

According to an example embodiment, when the sparse matrix is a symmetric matrix, the memory device controller 311 may more efficiently determine the plurality of rows by using the characteristics of the symmetric matrix. In an example embodiment, the sparse matrix used in GNN-related calculations may be a symmetric matrix. With regard thereto, if the i-th node and the j-th node are connect to each other, an element corresponding to (i,j) and (j,i) among elements of the sparse matrix may be a non-zero element. On the contrary, if the i-th node and the j-th node are not connected to each other, the element corresponding to (i,j) and (j,i) among the elements of the sparse matrix may be a zero element. Further, among the elements of the sparse matrix, elements located on the diagonal may be non-zero elements.

According to an example embodiment, when a plurality of rows include a first row and at least one second row, the at least one second row may be determined based on columns corresponding to non-zero elements included in the first row. In other words, at least one row may be determined heuristically based on the columns corresponding to the non-zero elements included in the first row. With respect thereto, referring to FIG. 7, a row 710 of a sparse matrix 700 which is a symmetric matrix may include a non-zero element 711 corresponding to the first column, a non-zero element 712 corresponding to the fourth column, a non-zero element 713 corresponding to the sixth column, a non-zero element 714 corresponding to the 10th column, and a non-zero element 715 corresponding to the 11th column. When the plurality of rows consist of a set number of rows, for example, three, at least one second row may be determined based on any two elements among the non-zero element 712, the non-zero element 713, the non-zero element 714 and the non-zero element 715. FIG. 7 illustrates that at least one second row is determined based on the fourth column corresponding to the non-zero element 712 and the sixth column corresponding to the non-zero element 713. With regard thereto, the row corresponding to the non-zero element 712 may be a fourth row 720 of the sparse matrix 700, and the row corresponding to the non-zero element 713 may be a sixth row 730 of the sparse matrix 700.

When calculations related to matrix multiplication according to the example embodiment of FIG. 6 is performed on a plurality of rows 740 including the row 710, the fourth row 720 and the sixth row 730, the number of times the second controller 150 sequentially transmits commands to the memory may be 8, which is the number of columns corresponding to non-elements included in the plurality of rows 740. In other words, by determining the plurality of rows using the characteristics of the symmetric matrix, the number of operations to read information about a vector from the memory may be significantly reduced. Accordingly, the time required for the memory controller 100 to perform calculations may also be greatly reduced.

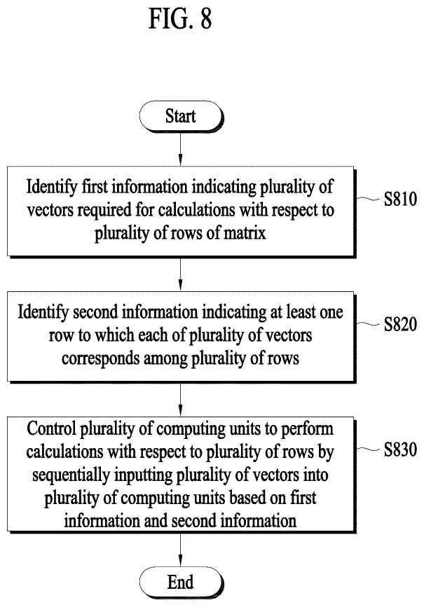

FIG. 8 is a flowchart illustrating an operation method of a memory controller according to an example embodiment.

Each operations of the operation method of FIG. 8 may be performed by the memory controller 100 described above, and thus descriptions that overlap the descriptions with respect to FIGS. 1 to 7 will be omitted. Here, the memory controller 100 may include the plurality of computing units 110 that perform calculations related to matrix multiplication, and the controller 120. The controller 120 may include the first controller 140 and the second controller 150 configured to perform operations to access data stored in the memory. The first controller 140 may include the matrix buffer 141 that stores the plurality of rows, the extractor 142 configured to identify the plurality of vectors and the at least one row to which each of the plurality of vectors corresponds, the first queue 143 that stores the first information and the second queue 144 that stores the second information. in case that the first queue 143 and the second queue 144 are empty, the extractor 142 is configured to identify the plurality of vectors related to operation S810 and the at least one row to which each of the plurality of vectors corresponds related to operation S820.

In operation S810, the memory controller 100 may identify first information indicating a plurality of vectors required for the calculations with respect to a plurality of rows of a matrix. The first information may include address information where each of the plurality of vectors is stored in a memory. The plurality of vectors may be identified based on columns corresponding to non-zero elements included in the plurality of rows.

According to an example embodiment, the plurality of rows are determined in order for non-zero elements comprised in a set number of rows of the matrix to be placed in an identical column in a maximum number. The set number may be determined based a size of the buffer 130 included in the memory controller 100. Alternatively, in case that the plurality of rows include the first row and at least one second row, the at least one second row is determined based on columns corresponding to non-zero elements comprised in the first row.

In operation S820, the memory controller 100 may identify second information indicating at least one row to which each of the plurality of vectors corresponds among the plurality of rows. The second information may include index information of at least one row to which each of the plurality of vectors corresponds among the plurality of rows. At least one first row corresponding to a first vector among the plurality of vectors may be identified based on a row of a first non-zero element comprised in a first column corresponding to the first vector.

According to an example embodiment, by sequentially searching the non-zero elements included in the plurality of rows of the matrix for each column in a preset order, the memory controller 100 may identify the plurality of vectors and at least one row to which each of the plurality of vectors corresponds.

According to an example embodiment, the first controller 140 may sequentially transmit the address information and the index information to the second controller 150. The second controller 150 may sequentially transmit commands comprising the address information to the memory. Here, the memory may include the DRAM, but is not limited thereto. The number of times that the commands are sequentially transmitted to the memory may be less than the number of non-zero elements comprised in the plurality of rows. More specifically, the number of times that the commands are sequentially transmitted to the memory is a number of columns that correspond to non-zero elements comprised in the plurality of rows. The second controller 150 may sequentially receive information about the plurality of vectors from the memory and transmit the information about the plurality of vectors to the plurality of computing units 110.

In operation S830, the memory controller 100 may control the plurality of computing units 110 to perform calculations with respect to the plurality of rows by sequentially inputting the plurality of vectors into the plurality of computing units 110 based on the first information and the second information. More specifically, by sequentially inputting plurality of vectors and non-zero elements into the plurality of computing units 110 based on the first information, the second information and the non-zero elements included in the plurality of rows, the memory controller 100 may control to plurality of computing units 110 to perform the calculations on the plurality of rows.

According to an example embodiment, the second information includes information about a first row and a second row among the plurality of rows to which a first vector among the plurality of vectors corresponds. The controller 120 is further configured to input a first vector into: i) the first computing unit 111, the first computing unit 111 corresponding to the first row, the plurality of computing units 110 comprising the first computing unit 111, and ii) the second computing unit 112, the second computing unit 112 corresponding to the second row, the plurality of computing units 110 comprising the second computing unit 112, control the first computing unit 111 to perform a first calculation for the first row, and control the second computing unit 112 to perform a second calculation for the second row.

According to an example embodiment, the buffer 130 included in the memory controller 100 may store result vectors related to the calculations, in case that the second information includes information about the first row among the plurality of rows to which the first vector among the plurality of vectors corresponds, a result vector corresponding to the first row is updated based on the calculation in the first computing unit 111 corresponding to the first row among the plurality of computing units.

According to an example embodiment, in case that an order of sequentially inputting the plurality of vectors comprises a second vector being input after a first vector is input, the controller 120 may be further configured to control the plurality of computing units 110 to perform a third calculation based on the first vector and then perform a fourth calculation based on the second vector.

According to an example embodiment, the memory controller 100 may include the interface 160. The interface 160 may receive commands to perform the calculations from the host system 310 comprising the memory device controller 311.

The memory controller 100 or a terminal according to the above-described example embodiments may include a processor, a memory for storing and executing program data, a permanent storage such as a disk drive, and/or a user interface device such as a communication port, a touch panel, a key and/or a button that communicates with an external device. Methods implemented as software modules or algorithms may be stored in a computer-readable recording medium as computer-readable codes or program instructions executable on the processor. Here, the computer-readable recording medium includes a magnetic storage medium (for example, ROMs, RAMs, floppy disks and hard disks) and an optically readable medium (for example, CD-ROMs and DVDs). The computer-readable recording medium may be distributed among network-connected computer systems, so that the computer-readable codes may be stored and executed in a distributed manner. The medium may be readable by a computer, stored in a memory, and executed on a processer.

The example embodiments may be represented by functional block elements and various processing steps. The functional blocks may be implemented in any number of hardware and/or software configurations that perform specific functions. For example, an example embodiment may adopt integrated circuit configurations, such as memory, processing, logic and/or look-up table, that may execute various functions by the control of one or more microprocessors or other control devices. Similar to that elements may be implemented as software programming or software elements, the example embodiments may be implemented in a programming or scripting language such as C, C++, Java, assembler, etc., including various algorithms implemented as a combination of data structures, processes, routines, or other programming constructs. Functional aspects may be implemented in an algorithm running on one or more processors. Further, the example embodiments may adopt the existing art for electronic environment setting, signal processing, and/or data processing. Terms such as “mechanism,” “element,” “means” and “configuration” may be used broadly and are not limited to mechanical and physical elements. The terms may include the meaning of a series of routines of software in association with a processor or the like.

The above-described example embodiments are merely examples, and other embodiments may be implemented within the scope of the claims to be described later.

What is claimed is:

1. A memory controller comprising:
a plurality of computing units, wherein the plurality of computing units is configured to perform calculations related to a matrix multiplication; and
a controller configured to:
identify first information indicating a plurality of vectors required for the calculations with respect to a plurality of rows of a matrix,
identify second information indicating at least one row to which each of the plurality of vectors corresponds among the plurality of rows, and
control the plurality of computing units to perform the calculations with respect to the plurality of rows by sequentially inputting the plurality of vectors into the plurality of computing units based on the first information and the second information.

2. The memory controller of claim 1, wherein the second information includes information about a first row and a second row among the plurality of rows to which a first vector among the plurality of vectors corresponds, and
wherein the controller is further configured to:
input a first vector into: i) a first computing unit, the first computing unit corresponding to the first row, the plurality of computing units comprising the first computing unit, and ii) a second computing unit, the second computing unit corresponding to the second row, the plurality of computing units comprising the second computing unit,
control the first computing unit to perform a first calculation for the first row, and
control the second computing unit to perform a second calculation for the second row.

3. The memory controller of claim 1, wherein the controller comprises:
a first controller that comprises a matrix buffer that stores the plurality of rows, an extractor configured to identify the plurality of vectors and the at least one row to which each of the plurality of vectors corresponds, a first queue that stores the first information and a second queue that stores the second information,
wherein the first information comprises address information where each of the plurality of vectors is stored in a memory, and
wherein the second information comprises index information of at least one row to which each of the plurality of vectors corresponds among the plurality of rows.

4. The memory controller of claim 3, wherein the extractor is configured to identify the plurality of vectors and the at least one row to which each of the plurality of vectors corresponds by sequentially searching for non-zero elements comprised in the plurality of rows for each column in a preset order.

5. The memory controller of claim 3, wherein the controller comprises a second controller configured to perform operations to access data stored in the memory,
wherein the first controller sequentially transmits the address information and the index information to the second controller, and
wherein the second controller sequentially transmits commands comprising the address information to the memory, sequentially receives information about the plurality of vectors from the memory and transmits the information about the plurality of vectors to the plurality of computing units.

6. The memory controller of claim 5, wherein a number of times that the commands are sequentially transmitted to the memory is less than a number of non-zero elements comprised in the plurality of rows.

7. The memory controller of claim 5, wherein a number of times that the commands are sequentially transmitted to the memory is a number of columns that correspond to non-zero elements comprised in the plurality of rows.

8. The memory controller of claim 1, wherein the plurality of vectors are identified based on columns corresponding to non-zero elements included in the plurality of rows, and
wherein at least one first row corresponding to a first vector among the plurality of vectors is identified based on a row of a first non-zero element comprised in a first column corresponding to the first vector.

9. The memory controller of claim 1, wherein the controller is further configured to control the plurality of computing units to perform the calculations with respect to the plurality of rows by sequentially inputting the plurality of vectors and non-zero elements into the plurality of computing units based on the first information, the second information and the non-zero elements comprised in the plurality of rows.

10. The memory controller of claim 1, comprising a buffer storing result vectors related to the calculations,
wherein, in case that the second information includes information about the first row among the plurality of rows to which the first vector among the plurality of vectors corresponds, a result vector corresponding to the first row is updated based on the calculation in a first computing unit corresponding to the first row among the plurality of computing units.

11. The memory controller of claim 1,
wherein an order of sequentially inputting the plurality of vectors comprises a second vector being input after a first vector is input, and
wherein the controller is further configured to control the plurality of computing units to perform a third calculation based on the first vector and then perform a fourth calculation based on the second vector.

12. The memory controller of claim 3, wherein the extractor, in case that the first queue and the second queue are empty, is configured to identify the plurality of vectors and the at least one row to which each of the plurality of vectors corresponds.

13. The memory controller of claim 1, comprising an interface,
wherein the interface receives commands to perform the calculations from a host system comprising a memory device controller.

14. The memory controller of claim 1, wherein the plurality of rows are determined in order for non-zero elements comprised in a set number of rows of the matrix to be placed in an identical column in a maximum number.

15. The memory controller of claim 1, wherein the plurality of rows comprises the first row and at least one second row,
wherein the at least one second row is determined based on columns corresponding to non-zero elements comprised in the first row.

16. The memory controller of claim 14, comprising a buffer, wherein the buffer is configured to store result vectors related to the calculations,
wherein the set number is determined based on a size of the buffer.

17. The memory controller of claim 3, wherein the memory comprises a dynamic random access memory (DRAM).

18. An operation method of a memory controller comprising a plurality of computing units configured to perform calculations related to a matrix multiplication and a controller, the operation method comprising:
identifying first information indicating a plurality of vectors required for the calculations with respect to a plurality of rows of a matrix,
identifying second information indicating at least one row to which each of the plurality of vectors corresponds among the plurality of rows, and
controlling the plurality of computing units to perform the calculations with respect to the plurality of rows by sequentially inputting the plurality of vectors into the plurality of computing units based on the first information and the second information.

19. A non-transitory computer-readable recording medium having a program for executing the operation method of claim 18 on a computer.

20. A memory system comprising:
a host system comprising a memory device controller; and
a plurality of memory controllers that operate according to commands received from the memory device controller,
wherein the plurality of memory controllers comprises a first memory controller,
wherein the first memory controller comprises:
a plurality of computing units configured to perform calculations related to a matrix multiplication; and
a controller configured to:
identify first information indicating a plurality of vectors required for the calculations with respect to a plurality of rows of a matrix,
identify second information indicating at least one row to which each of the plurality of vectors corresponds among the plurality of rows, and
control the plurality of computing units to perform the calculations with respect to the plurality of rows by sequentially inputting the plurality of vectors into the plurality of computing units based on the first information and the second information.
